(19) United States
(12) Patent Application Publication
(10) Pub. No.: US 2026/0314264 A1
(43) Pub. Date: Oct. 8, 2026

(54) ACTUATOR

(71) Applicant: Murata Manufacturing Co., Ltd., Nagaokakyo-shi (JP)

(72) Inventor: Masaaki FUJISAKI, Nagaokakyo-shi (JP)

(21) Appl. No.: 19/682,492

(22) Filed: May 20, 2026

Related U.S. Application Data
(63) Continuation of application No. PCT/JP2024/043180, filed on Dec. 6, 2024.

(30) Foreign Application Priority Data
Dec. 21, 2023 (JP) 2023-215779
Nov. 13, 2024 (JP) 2024-197946

(51) Int. Cl. H10N 30/20; F04B 43/04

(52) U.S. Cl. CPC H10N 30/204; F04B 43/046

(57) ABSTRACT

An actuator includes a piezoelectric body having a first main surface and a second main surface, a first electrode disposed on the first main surface, a second electrode disposed on the second main surface, a first vibrating plate disposed on the first electrode, and a second vibrating plate disposed on the second electrode. A thickness of the first vibrating plate differs from a thickness of the second vibrating plate, and fillets are formed between a peripheral edge of the piezoelectric body and the first vibrating plate and between the peripheral edge of the piezoelectric body and the second vibrating plate.

### CROSS REFERENCE TO RELATED APPLICATION

This is a continuation of International Application No. PCT/JP2024/043180 filed on December 6, 2024 which claims priority from Japanese Patent Application No. 2023-215779 filed on December 21, 2023 and Japanese Patent Application No. 2024-197946 filed on November 13, 2024. The contents of these applications are incorporated herein by reference in their entireties.

### BACKGROUND OF THE DISCLOSURE

### Field of the Disclosure

The present disclosure relates to an actuator that includes vibrating plates.

### Description of the Related Art

International Publication No. 2011/145544 discloses an actuator in which a plate-shaped piezoelectric element is attached to a plate-shaped vibrating plate. The actuator performs flexural vibration from its center toward its outer periphery in accordance with a drive voltage. A peripheral portion of the actuator is substantially not constrained.

Japanese Unexamined Patent Application Publication No. 2009-293507 discloses a configuration in which a first vibrating plate and a second vibrating plate are attached to a first main surface and a second main surface, respectively, of a piezoelectric body.

### BRIEF SUMMARY OF THE DISCLOSURE

In the structure of International Publication No. 2011/145544, when the amplitude of the actuator is increased in order to increase output, the piezoelectric body may crack and fail.

The structure of Japanese Unexamined Patent Application Publication No. 2009-293507 can prevent the piezoelectric body from cracking; however, when the configuration of Japanese Unexamined Patent Application Publication No. 2009-293507 is applied to the structure of International Publication No. 2011/145544, the unconstrained peripheral portions of the first vibrating plate and the second vibrating plate may contact each other and cause a short circuit.

Accordingly, it is a possible benefit of the present disclosure to provide an actuator capable of preventing the piezoelectric body from cracking and also preventing the unconstrained peripheral portions of the first vibrating plate and the second vibrating plate from contacting each other and causing a short circuit.

An actuator according to an embodiment of the present disclosure includes a piezoelectric body having a first main surface and a second main surface, a first electrode disposed on the first main surface, a second electrode disposed on the second main surface, a first vibrating plate disposed on the first electrode, and a second vibrating plate disposed on the second electrode. A thickness of the first vibrating plate differs from a thickness of the second vibrating plate, and fillets are formed between a peripheral edge of the piezoelectric body and the first vibrating plate and between the peripheral edge of the piezoelectric body and the second vibrating plate.

An actuator according to another embodiment of the present disclosure includes a first piezoelectric body having a first main surface and a second main surface, a first electrode disposed on the first main surface, a second electrode disposed on the second main surface, a second piezoelectric body having a third main surface and a fourth main surface, a third electrode disposed on the third main surface, a fourth electrode disposed on the fourth main surface, a first vibrating plate disposed on the first electrode, a second vibrating plate disposed on the second electrode and the third electrode, and a third vibrating plate disposed on the fourth electrode. Fillets are formed between a peripheral edge of the first piezoelectric body and the first vibrating plate, between the peripheral edge of the first piezoelectric body and the second vibrating plate, between a peripheral edge of the second piezoelectric body and the second vibrating plate, and between the peripheral edge of the second piezoelectric body and the third vibrating plate.

Since the actuator includes the vibrating plates on both main surfaces of the piezoelectric body, failure of the piezoelectric body caused by cracking can be prevented. Further, the fillets formed between the peripheral edge of the piezoelectric body and the vibrating plates suppress bending of the peripheral portions of the two vibrating plates toward each other, thereby preventing the unconstrained peripheral portions of the two vibrating plates from contacting each other and causing a short circuit.

According to the present disclosure, it is possible to prevent the piezoelectric body from cracking and prevent the unconstrained peripheral portions of the first vibrating plate and the second vibrating plate from contacting each other and causing a short circuit.

### BRIEF DESCRIPTION OF THE SEVERAL VIEWS OF THE DRAWINGS

FIG. 1 is a sectional view of an actuator 1.

FIG. 2 is a plan view of a first vibrating plate 11.

FIG. 3 is a plan view of a piezoelectric body 10.

FIG. 4 is a sectional view of the actuator 1 during flexural vibration.

FIG. 5 is a sectional view of an actuator according to a reference example during flexural vibration.

FIG. 6 is a sectional view of an actuator 2.

FIG. 7 is a sectional view of the actuator 2 during flexural vibration.

FIG. 8 is a graph showing a relationship between the distance from a neutral plane to a main surface of a piezoelectric body (the main surface on the side farther from the neutral plane) and stress/amplitude (i.e., stress per unit amplitude).

FIG. 9 is a graph showing a relationship between the distance from the neutral plane to the main surface of the piezoelectric body and amplitude.

FIG. 10 is a graph showing a relationship between amplitude and radial stress at the center of the piezoelectric body.

FIG. 11 is a sectional view showing a structure of Modification 1 of a bimorph.

FIG. 12 is a sectional view showing a structure of Modification 2 of the bimorph.

FIG. 13 is a plan view showing a structure of Modification 3 of the bimorph.

FIG. 14 is a sectional view showing the structure of Modification 3 of the bimorph.

FIG. 15 is an exploded perspective view showing a structure of Modification 4 of the bimorph.

FIG. 16 is an exploded perspective view of an actuator 2E according to Modification 5.

FIG. 17 is a sectional view showing the first vibrating plate 11 and a portion below the first vibrating plate 11 of the actuator 2E.

FIG. 18 is a sectional view showing the first vibrating plate 11 and the portion below the first vibrating plate 11 of the actuator 2E.

FIG. 19 is a sectional view showing a structure of Modification 6 of the bimorph.

FIG. 20 is a partially enlarged view of FIG. 19.

FIG. 21A is a plan view of electrode patterns D122A and D122B formed on an insulating layer LY121 and FIG. 21B is a plan view of electrode patterns D123A and D123B formed on an insulating layer LY122.

FIG. 22 is a plan view of electrode patterns, via electrodes, and through-holes formed between the insulating layer LY121 and the insulating layer LY122.

FIG. 23A is a plan view of the insulating layer LY121 and FIG. 23B is a plan view of the insulating layer LY122.

### DETAILED DESCRIPTION OF THE DISCLOSURE

An actuator according to a first embodiment of the present disclosure will be described with reference to the accompanying drawings. Note that, in each of the drawings illustrating the following embodiments, the shapes of the respective components are partially or entirely exaggerated for ease of understanding.

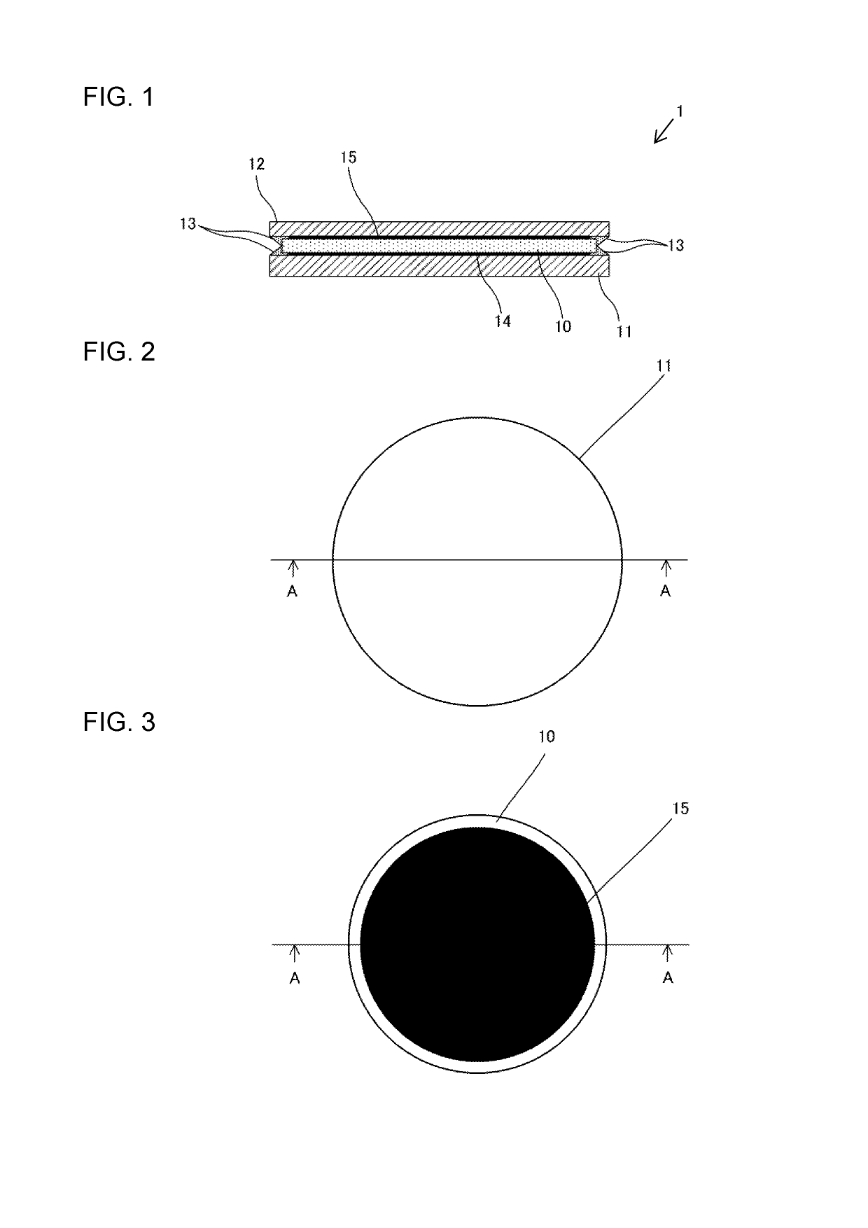

FIG. 1 is a sectional view of an actuator 1 according to the first embodiment of the present disclosure. The actuator 1 includes a piezoelectric body 10, a first vibrating plate 11, a second vibrating plate 12, fillets 13, a first electrode 14, and a second electrode 15.

FIG. 2 is a plan view of the first vibrating plate 11, and FIG. 3 is a plan view of the piezoelectric body 10. The sectional view of FIG. 1 is a sectional view taken along line A-A shown in FIGS. 2 and 3.

The piezoelectric body 10 is composed of, for example, a lead zirconate titanate ceramic. The piezoelectric body 10 has a thin disk shape. The first electrode 14 is formed on a first main surface of the piezoelectric body 10 by, for example, sputtering or the like, and the second electrode 15 is formed on a second main surface of the piezoelectric body 10 by, for example, sputtering or the like. The piezoelectric body 10 is strained by a drive voltage applied to the first electrode 14 and the second electrode 15. In the present embodiment, when viewed in plan view, the outer diameter of the piezoelectric body 10 is greater than each of the outer diameters of the first electrode 14 and the second electrode 15.

The first vibrating plate 11 is attached to the first electrode 14 with an adhesive. The second vibrating plate 12 is attached to the second electrode 15 with an adhesive. The adhesive contains a plurality of conductive fillers. When the thickness of the adhesive becomes equal to or less than a predetermined value, the plurality of conductive fillers electrically connect the electrode and the vibrating plate. On the other hand, an insulating resin is present between the fillers, which has no conductivity. Accordingly, the adhesive becomes conductive in the thickness direction when its thickness is equal to or less than a predetermined thickness, and becomes insulating when its thickness exceeds the predetermined thickness. For example, the adhesive in the portion sandwiched between the first electrode 14 and the first vibrating plate 11, and the adhesive in the portion sandwiched between the second electrode 15 and the second vibrating plate 12, each have a thickness equal to or less than the predetermined thickness, and therefore are conductive.

The first vibrating plate 11 and the second vibrating plate 12 each have a disk shape. In the present embodiment, the first vibrating plate 11 and the second vibrating plate 12 have the same shape in plan view. In the present embodiment, when viewed in plan view, the outer diameter of the piezoelectric body 10 is smaller than each of the outer diameters of the first vibrating plate 11 and the second vibrating plate 12.

The thickness of the first vibrating plate 11 differs from the thickness of the second vibrating plate 12. In the present embodiment, the first vibrating plate 11 is thicker than the second vibrating plate 12. However, the first vibrating plate 11 may be thinner than the second vibrating plate 12. Accordingly, the second vibrating plate 12 is more easily deformable and more easily bendable than the first vibrating plate 11.

The first vibrating plate 11 and the second vibrating plate 12 are made of a conductive material. Conductor wires (not shown) are connected to the first vibrating plate 11 and the second vibrating plate 12. A drive circuit is electrically connected to the conductor wires and to the first vibrating plate 11 and the second vibrating plate 12. Thus, a drive voltage is applied to the first vibrating plate 11 and the second vibrating plate 12. The first vibrating plate 11 and the second vibrating plate 12 are attached to the first electrode 14 and the second electrode 15, respectively, by the above-described adhesive. Accordingly, the drive voltage is applied to the first electrode 14 and the second electrode 15.

The actuator 1 is designed to vibrate at a predetermined resonant frequency. A drive voltage having a frequency corresponding to the resonant frequency is applied to the first electrode 14 and the second electrode 15. Thus, the actuator 1 performs rotationally symmetric (concentric) flexural vibration from its central portion toward its peripheral portion.

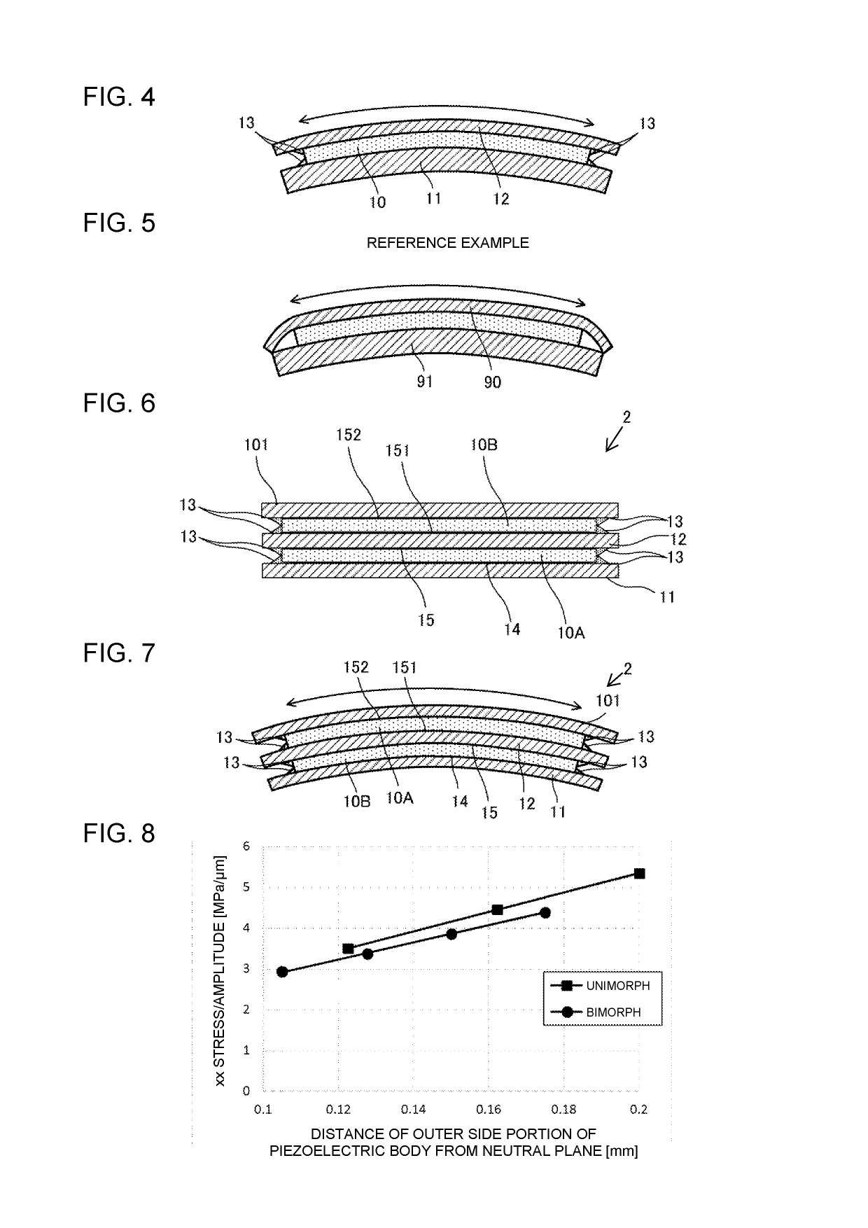

FIG. 4 is a sectional view of the actuator 1 during flexural vibration. Arrows in FIG. 4 indicate the deformation direction of the piezoelectric body 10. FIG. 4 shows, as an example, a case where the piezoelectric body 10 contracts in a direction parallel to the main surfaces.

When a drive voltage that causes the piezoelectric body 10 to contract in a direction parallel to the main surfaces is applied to the first vibrating plate 11 or the second vibrating plate 12, the actuator 1 deforms in a manner shown in FIG. 4. As shown in FIG. 4, when the piezoelectric body 10 expands in a direction parallel to the main surfaces, since the first vibrating plate 11 is thicker than the second vibrating plate 12, the centers of the piezoelectric body 10, the first vibrating plate 11, and the second vibrating plate 12 are bent and deformed in a convex shape along the normal direction. Further, when the piezoelectric body 10 contracts in a direction parallel to the main surfaces, the centers of the piezoelectric body 10, the first vibrating plate 11, and the second vibrating plate 12 are bent and deformed in a concave shape along the normal direction.

Accordingly, the actuator 1 of the present embodiment functions as a piezoelectric unimorph vibrator. Such an actuator 1 functions, for example, as a piezoelectric pump when incorporated in a pump chamber having a vent hole.

Since the peripheral portion of the actuator 1 of the present embodiment is not constrained, a large amplitude can be obtained despite its compact and low-profile structure. Further, the first vibrating plate 11 and the second vibrating plate 12 are disposed on both main surfaces (the first main surface and the second main surface) of the piezoelectric body 10 in the actuator 1 of the present embodiment. Therefore, even when the amplitude of the actuator is increased in order to increase output, there is no risk that the piezoelectric body 10 will crack. In particular, in the actuator 1, when viewed in plan view, the outer diameter of the piezoelectric body 10 is smaller than each of the outer diameters of the first vibrating plate 11 and the second vibrating plate 12. Therefore, the side surface of the piezoelectric body 10 is less likely to be directly touched, particularly during dropping or transport, so that damage can be further suppressed.

Further, in the actuator 1 of the present embodiment, fillets 13 are formed between the peripheral edge of the piezoelectric body 10 and the first vibrating plate 11 and between the peripheral edge of the piezoelectric body 10 and the second vibrating plate 12. The fillets 13 are formed by overflow of the above-described adhesive. The adhesive constituting the fillets 13 has a thickness greater than the predetermined thickness and therefore is insulating. In the actuator 1 of the present embodiment, even in a state where the peripheral portions are not constrained by a rigid body other than the fillets 13, the fillets 13 are interposed between the first vibrating plate 11 and the second vibrating plate 12, thereby preventing the peripheral portions of the first vibrating plate 11 and the second vibrating plate 12 from contacting each other and causing a short circuit.

FIG. 5 is a sectional view of an actuator according to a reference example during flexural vibration. As shown in FIG. 5, in an actuator having no fillets 13, when the center of a vibrating plate 90 is bent and deformed in a convex shape along the normal direction, since the peripheral portion of the vibrating plate 90 is not constrained, the peripheral portion of the vibrating plate 90 is caused to bend toward another vibrating plate 91 opposed to the vibrating plate 90. Therefore, the vibrating plates 90 and 91 may contact each other and cause a short circuit.

In contrast, in the actuator 1 of the present embodiment, the fillets 13 interposed between the first vibrating plate 11 and the second vibrating plate 12 suppress the peripheral portion of the second vibrating plate 12 from bending toward the opposing first vibrating plate 11 due to the peripheral portion being unconstrained. Further, the fillets 13 interposed between the first vibrating plate 11 and the second vibrating plate 12 can prevent the peripheral portions of the first vibrating plate 11 and the second vibrating plate 12 from directly contacting each other and causing a short circuit.

In the actuator 1 of the present embodiment, when viewed in plan view, the area of the piezoelectric body 10 is larger than each of the areas of the first electrode 14 and the second electrode 15. Although such a configuration is not essential in the present disclosure, such a configuration prevents the electrodes (the first electrode 14 and the second electrode 15) from protruding to the side surface of the piezoelectric body 10. Therefore, during formation of the electrodes, the electrodes do not wrap around to the side surface of the piezoelectric body 10, so that a short circuit can be suppressed.

Next, FIG. 6 is a sectional view of an actuator 2 according to a second embodiment. Note that, in the description of the actuator 2, components similar to those of the actuator 1 shown in FIG. 1 are denoted by the same reference signs, and descriptions thereof will be omitted. The actuator 2 includes a first piezoelectric body 10A, the first vibrating plate 11, the second vibrating plate 12, the fillets 13, the first electrode 14, the second electrode 15, a second piezoelectric body 10B, a third vibrating plate 101, a third electrode 151, and a fourth electrode 152.

The first piezoelectric body 10A has the same configuration and function as the piezoelectric body 10 of the first embodiment. The second piezoelectric body 10B has the same structure as the first piezoelectric body 10A. The second piezoelectric body 10B has a third main surface and a fourth main surface. The third electrode 151 is formed on the third main surface of the second piezoelectric body 10B by, for example, sputtering or the like, and the fourth electrode 152 is formed on the fourth main surface thereof by, for example, sputtering or the like.

The second vibrating plate 12 is attached to the third electrode 151 with an adhesive. The third vibrating plate 101 is attached to the fourth electrode 152 with an adhesive. Accordingly, in the actuator 2 of the present embodiment, the fillets 13 are formed between the peripheral edge of the first piezoelectric body 10A and the first vibrating plate 11, between the peripheral edge of the first piezoelectric body 10A and the second vibrating plate 12, between the peripheral edge of the second piezoelectric body 10B and the second vibrating plate 12, and between the peripheral edge of the second piezoelectric body 10B and the third vibrating plate 101.

The third vibrating plate 101 has a disk shape. In the present embodiment, the first vibrating plate 11 and the third vibrating plate 101 have the same shape and have the same outer diameter in plan view.

In the present embodiment, when viewed in plan view, each of the outer diameters of the first piezoelectric body 10A and the second piezoelectric body 10B is smaller than each of the outer diameters of the first vibrating plate 11 and the third vibrating plate 101.

In the present embodiment, the first vibrating plate 11, the second vibrating plate 12, and the third vibrating plate 101 all have the same shape and the same outer diameter. The thicknesses of the first vibrating plate 11, the second vibrating plate 12, and the third vibrating plate 101 are also the same. However, the second vibrating plate 12 may be thinner or thicker than the first vibrating plate 11 and the third vibrating plate 101.

A drive voltage is applied to the first vibrating plate 11, the second vibrating plate 12, and the third vibrating plate 101. A drive voltage having a frequency corresponding to the resonant frequency of the actuator 2 is applied to the first vibrating plate 11, the second vibrating plate 12, and the third vibrating plate 101. The drive voltage is applied to the first electrode 14, the second electrode 15, the third electrode 151, and the fourth electrode 152. Since the second electrode 15 and the third electrode 151 are attached to the second vibrating plate 12, they are at the same potential. Drive voltages of opposite polarities relative to the potential of the second vibrating plate 12 are applied to the first electrode 14 and the fourth electrode 152.

FIG. 7 is a sectional view of the actuator 2 during flexural vibration. In the example of FIG. 7, the first piezoelectric body 10A expands in a direction parallel to the main surfaces, and the second piezoelectric body 10B contracts in a direction parallel to the main surfaces. In such a case, the centers of the first vibrating plate 11, the second piezoelectric body 10B, the second vibrating plate 12, the first piezoelectric body 10A, and the third vibrating plate 101 are bent and deformed in a convex shape along the normal direction. Although not shown in the drawings, when the first piezoelectric body 10A contracts in a direction parallel to the main surfaces, the second piezoelectric body 10B expands in a direction parallel to the main surfaces. In such a case, the centers of the first vibrating plate 11, the second piezoelectric body 10B, the second vibrating plate 12, the first piezoelectric body 10A, and the third vibrating plate 101 are bent and deformed in a concave shape along the normal direction. The central position of the second vibrating plate 12 in the vertical direction is a neutral plane where stress in a direction parallel to the main surfaces is substantially zero.

Accordingly, the actuator 2 of the present embodiment functions as a piezoelectric bimorph vibrator. Such an actuator 2 also functions, for example, as a piezoelectric pump when incorporated in a pump chamber having a vent hole.

Also, in the actuator 2, since the peripheral portion is not constrained, a large amplitude can be obtained despite its compact and low-profile structure. Further, vibrating plates are disposed on both main surfaces of each of the first piezoelectric body 10A and the second piezoelectric body 10B in the actuator 2. Therefore, even when the amplitude of the actuator is increased in order to increase output, there is no risk that the piezoelectric bodies will crack. In particular, in the actuator 2, when viewed in plan view, each of the outer diameters of the first piezoelectric body 10A and the second piezoelectric body 10B is smaller than each of the outer diameters of the first vibrating plate 11 and the third vibrating plate 101, which are located on the outer side portions of the actuator 2. Therefore, the side surfaces of the first piezoelectric body 10A and the second piezoelectric body 10B are less likely to be directly touched, particularly during dropping or transport, so that damage can be further suppressed.

Further, in the actuator 2 of the present embodiment, the fillets 13 are formed between the peripheral edge of the first piezoelectric body 10A and the first vibrating plate 11, between the peripheral edge of the first piezoelectric body 10A and the second vibrating plate 12, between the peripheral edge of the second piezoelectric body 10B and the second vibrating plate 12, and between the peripheral edge of the second piezoelectric body 10B and the third vibrating plate 101. The fillets 13 are formed by overflow of the above-described adhesive. In the actuator 2 of the present embodiment, even in a state where the peripheral portions are not constrained, contact between the peripheral portions of the first vibrating plate 11 and the second vibrating plate 12 can be prevented. Further, in the actuator 2 of the present embodiment, even in a state where the peripheral portions are not constrained, contact between the peripheral portions of the second vibrating plate 12 and the third vibrating plate 101 can be prevented. Further, in the actuator 2 of the present embodiment, even in a state where the peripheral portions are not constrained, contact between the peripheral portions of the first vibrating plate 11 and the third vibrating plate 101 can be prevented.

Further, compared with the actuator 1, which is a piezoelectric unimorph vibrator, the actuator 2 can convert the drive voltage into flexural vibration more efficiently even under the same drive voltage, so that the amplitude per unit voltage can be increased.

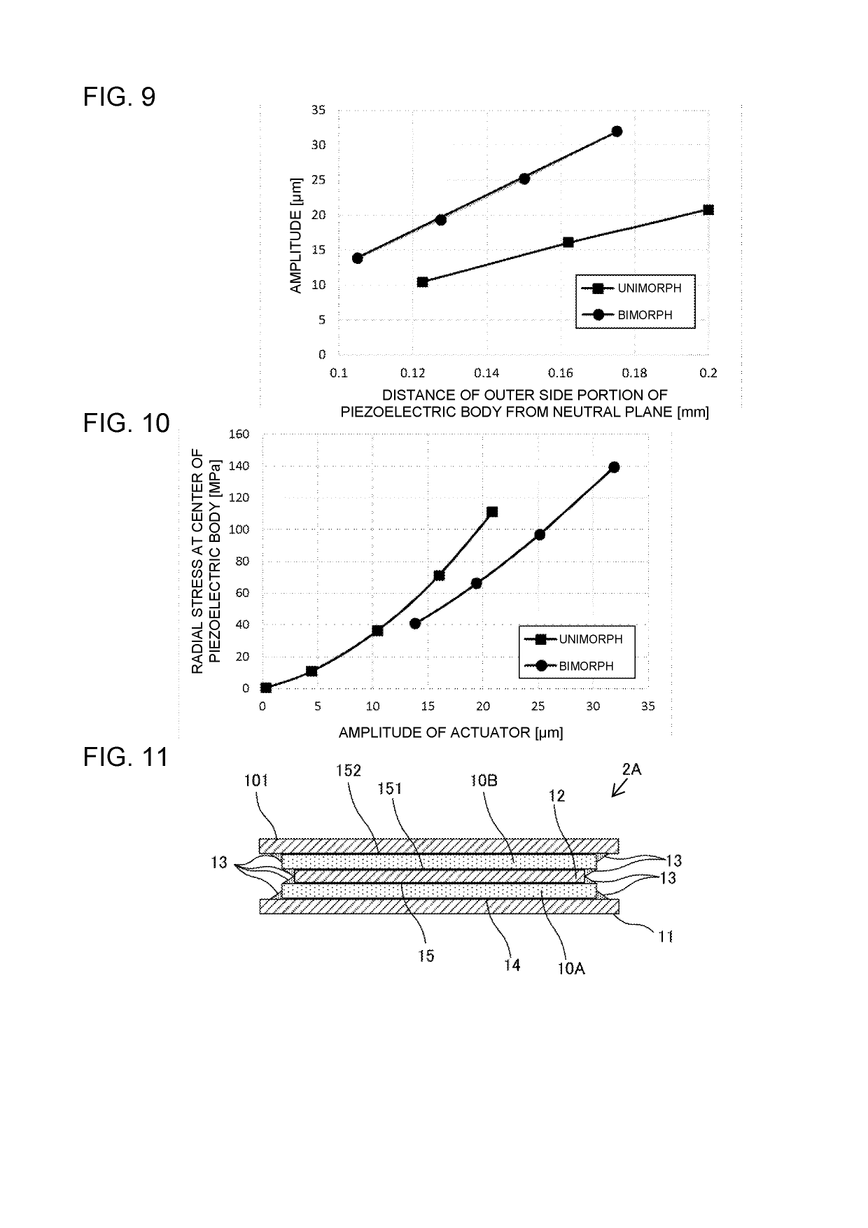

FIG. 8 is a graph showing a relationship between the distance from a neutral plane to a main surface of a piezoelectric body (the main surface on the side farther from the neutral plane) and stress/amplitude (stress per unit amplitude), and FIG. 9 is a graph showing a relationship between the distance from the neutral plane to the main surface of the piezoelectric body and amplitude. FIG. 10 is a graph showing a relationship between amplitude and radial stress at the center of the piezoelectric body. In all cases, the thicknesses of the vibrating plates are adjusted such that the resonant frequencies become equal. The stress shown in FIG. 8 is stress generated in a planar direction from the main surface of the piezoelectric body at the central position when the piezoelectric body is viewed in plan view. The stress shown in FIG. 10 is stress generated in the radial direction (the planar direction) from the main surface of the piezoelectric body at the central position when the piezoelectric body is viewed in plan view. The term "unimorph" shown in FIGS. 8 to 10 corresponds to the structure of the actuator 1, and the term "bimorph" corresponds to the structure of the actuator 2.

As shown in FIG. 8, in both the unimorph and the bimorph, the stress per unit amplitude increases as the distance from the neutral plane to the main surface of the piezoelectric body increases. Further, when the distance from the neutral plane to the main surface of the piezoelectric body is the same in the unimorph and the bimorph, the stress generated in the piezoelectric body is slightly greater in the unimorph than in the bimorph. On the other hand, as shown in FIG. 9, when the distance from the neutral plane to the main surface of the piezoelectric body is the same in the unimorph and the bimorph, the amplitude of the actuator is much greater in the bimorph than in the unimorph. Further, as shown in FIG. 10, when the radial stress at the center of the piezoelectric body is the same in the unimorph and the bimorph, the amplitude of the actuator is much greater in the bimorph than in the unimorph.

As shown in the sectional views of FIGS. 4 and 7, in the unimorph, the vibrating plates are attached to both main surfaces of the piezoelectric body, whereby flexural vibration is inhibited and the component of expansion/contraction vibration increases; in contrast, in the bimorph, even when the vibrating plates are attached to both main surfaces of the piezoelectric bodies, the paired piezoelectric bodies expand and contract in opposite directions and the drive voltage is efficiently converted into flexural vibration. Therefore, in the bimorph, the vibrating plate at the outermost layer of the actuator can be made thicker for resonant-frequency adjustment, so that the neutral plane and the main surfaces of the piezoelectric bodies become closer to each other than in the unimorph. Therefore, the stress per unit amplitude applied to the piezoelectric bodies is reduced. In other words, even under the same stress, the amplitude of the actuator is much greater in the bimorph.

Accordingly, in a bimorph such as the actuator 2, the piezoelectric bodies are less likely to be damaged when the output is increased to increase the amplitude, as compared with a unimorph such as the actuator 1.

Next, FIG. 11 is a sectional view showing a structure of Modification 1 of the bimorph. In an actuator 2A according to Modification 1 shown in FIG. 11, each of the outer diameters of the first piezoelectric body 10A and the second piezoelectric body 10B in plan view is larger than the outer diameter of the second vibrating plate 12. Thus, the first piezoelectric body 10A is present between the end portion of the first vibrating plate 11 and the end portion of the second vibrating plate 12, and the second piezoelectric body 10B is present between the end portion of the third vibrating plate 101 and the end portion of the second vibrating plate 12. Therefore, the possibility of occurrence of contact between the first vibrating plate 11 and the second vibrating plate 12, and between the third vibrating plate 101 and the second vibrating plate 12, during vibration, can be further reduced, and the possibility of short circuit can be further suppressed.

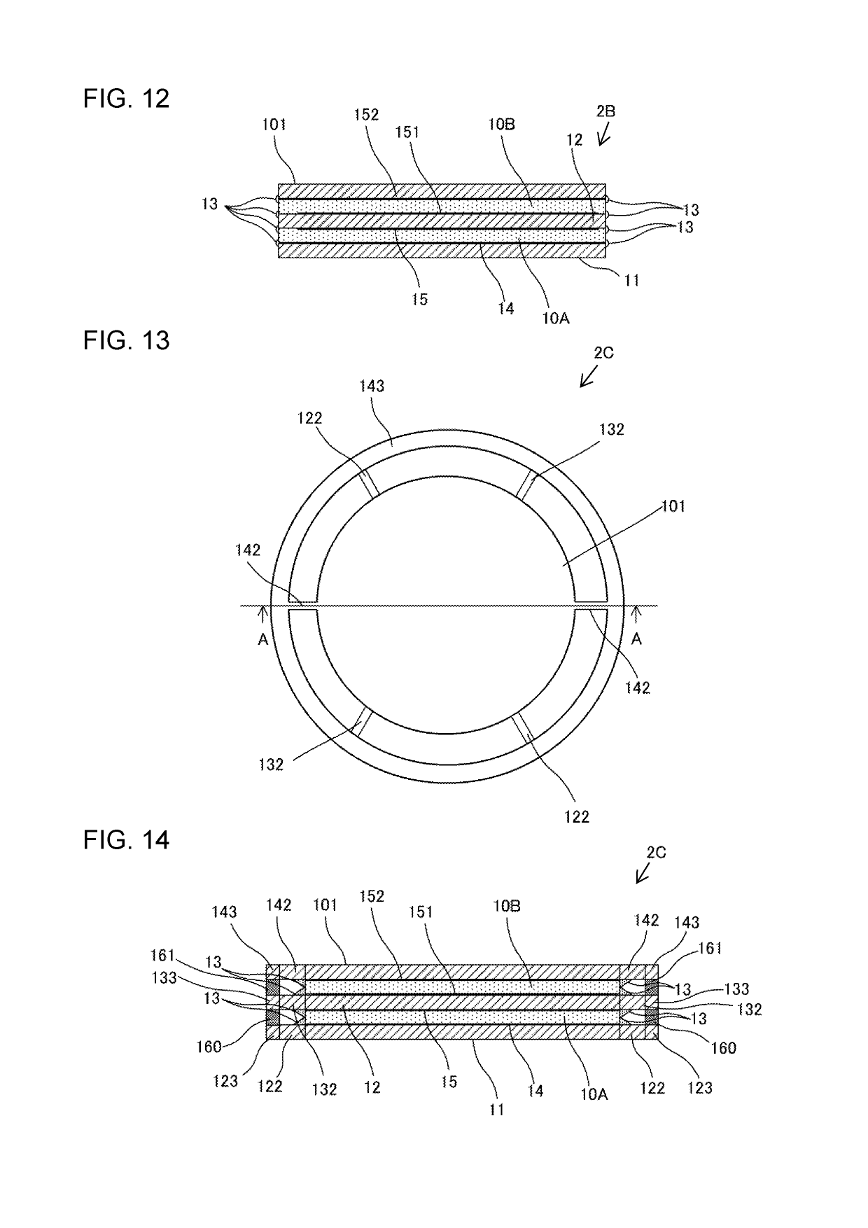

FIG. 12 is a sectional view showing a structure of Modification 2 of the bimorph. In an actuator 2B according to Modification 2 shown in FIG. 12, the outer diameters of the first piezoelectric body 10A, the second piezoelectric body 10B, the first vibrating plate 11, the second vibrating plate 12, and the third vibrating plate 101 in plan view are all the same.

Also, in the actuator 2B, the fillets 13 are formed between the peripheral edge of the first piezoelectric body 10A and the first vibrating plate 11, between the peripheral edge of the first piezoelectric body 10A and the second vibrating plate 12, between the peripheral edge of the second piezoelectric body 10B and the second vibrating plate 12, and between the peripheral edge of the second piezoelectric body 10B and the third vibrating plate 101. Also, in the actuator 2B, the vibrating plates are disposed on both main surfaces of each of the first piezoelectric body 10A and the second piezoelectric body 10B. Therefore, even when the amplitude of the actuator is increased in order to increase output, there is no risk that the piezoelectric bodies will crack.

Next, FIG. 13 is a plan view showing a structure of Modification 3 of the bimorph, and FIG. 14 is a sectional view showing the same. According to Modification 3, the first vibrating plate 11, the second vibrating plate 12, and the third vibrating plate 101 all have the same shape, the same thickness, and the same outer diameter. A first frame body 123, a second frame body 133, and a third frame body 143 each have an annular shape surrounding the first vibrating plate 11, the second vibrating plate 12, and the third vibrating plate 101, respectively. An upper main surface of the first frame body 123 and a lower main surface of the second frame body 133 are connected to each other with a spacer 160 interposed therebetween. The spacer 160 has the same inner diameter and outer diameter as those of the first frame body 123 and the second frame body 133. The thickness of the spacer 160 is substantially the same as the thickness of the first piezoelectric body 10A. The first vibrating plate 11 and the second vibrating plate 12 face each other with the spacer 160 interposed therebetween.

An upper main surface of the second frame body 133 and a lower main surface of the third frame body 143 are connected to each other with a spacer 161 interposed therebetween. The spacer 161 has the same inner diameter and outer diameter as those of the second frame body 133 and the third frame body 143. The thickness of the spacer 161 is substantially the same as the thickness of the second piezoelectric body 10B. The second vibrating plate 12 and the third vibrating plate 101 face each other with the spacer 161 interposed therebetween.

A first connecting portion 122, a second connecting portion 132, and a third connecting portion 142 extend from the outer peripheries of the first vibrating plate 11, the second vibrating plate 12, and the third vibrating plate 101, respectively, and are connected to the first frame body 123, the second frame body 133, and the third frame body 143, respectively. The first connecting portion 122, the second connecting portion 132, and the third connecting portion 142 elastically support the first vibrating plate 11, the second vibrating plate 12, and the third vibrating plate 101, respectively. The first connecting portion 122, the second connecting portion 132, and the third connecting portion 142 are arranged at equal intervals (at 60-degree intervals in Modification 3) from each other in plan view, and do not overlap with each other in plan view.

Thus, an actuator 2C has regions in which the vibrating plates of different polarities do not overlap with each other in plan view. Thus, during vibration of the actuator 2C, the connecting portions do not contact each other, and therefore a short circuit can be suppressed.

The configuration in which the connecting portions connecting the vibrating plates and the frame bodies do not overlap with each other in plan view is not limited to the bimorph structure and may also be applied to the unimorph structure.

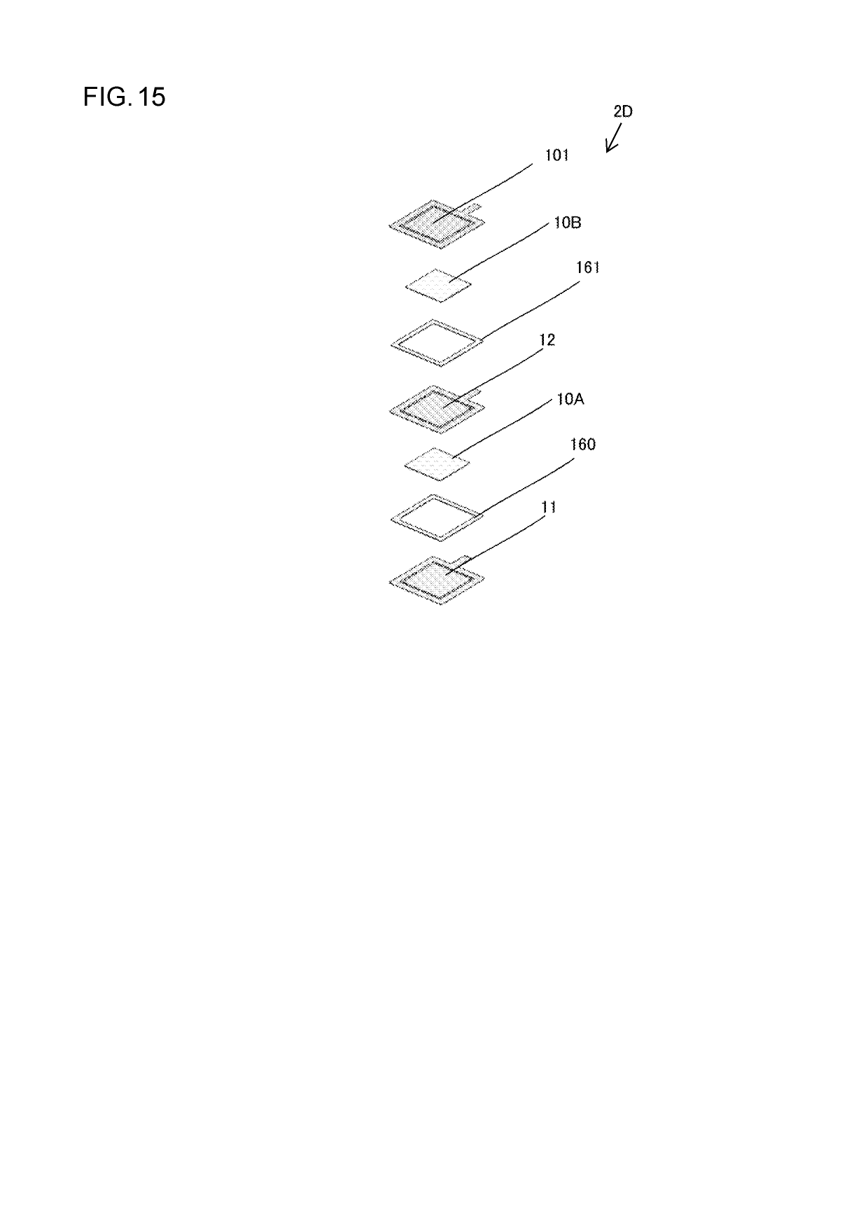

Next, FIG. 15 is an exploded perspective view showing a structure of Modification 4 of the bimorph. An actuator 2D according to Modification 4 has a rectangular shape in plan view. The actuator 2D has the same configuration and functions as the actuator 2C shown in FIG. 13, except that the actuator 2D has a rectangular shape in plan view. Thus, the actuator according to the present disclosure may have a rectangular shape in plan view.

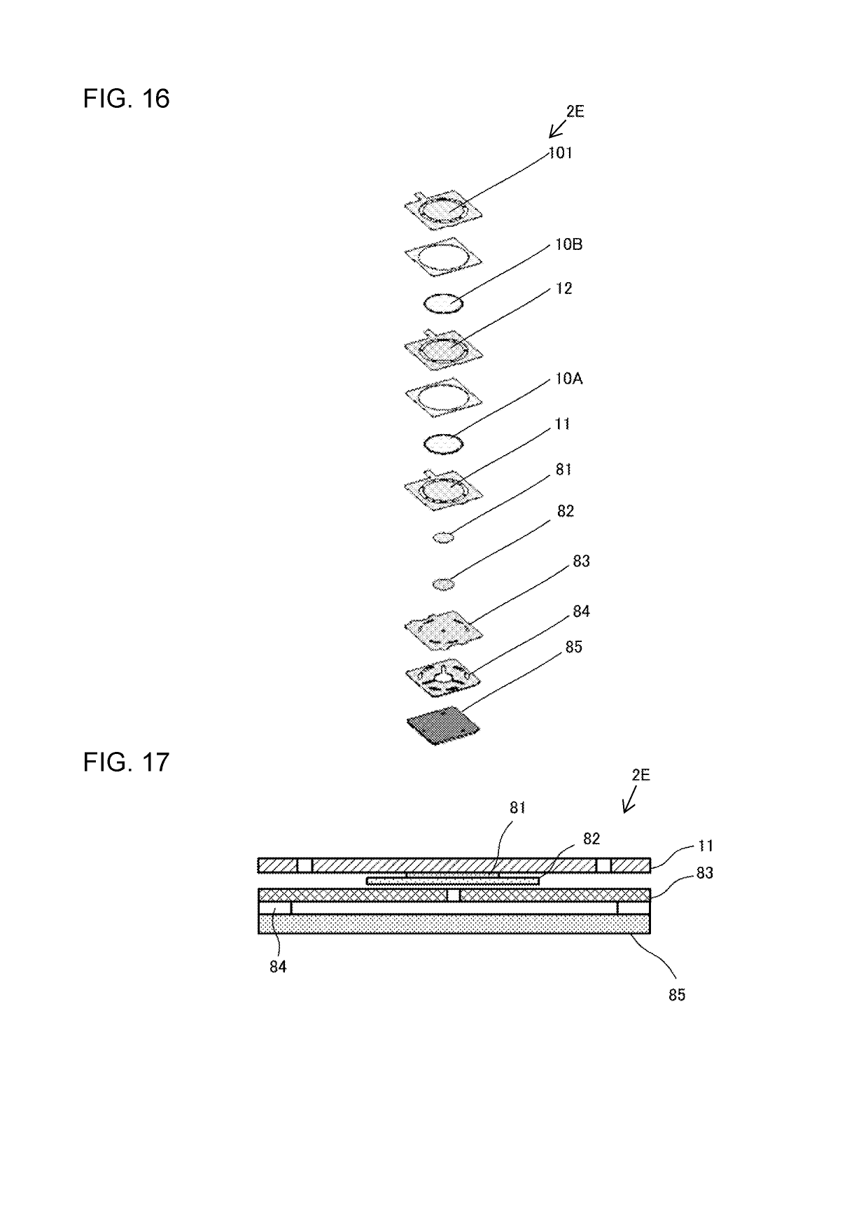

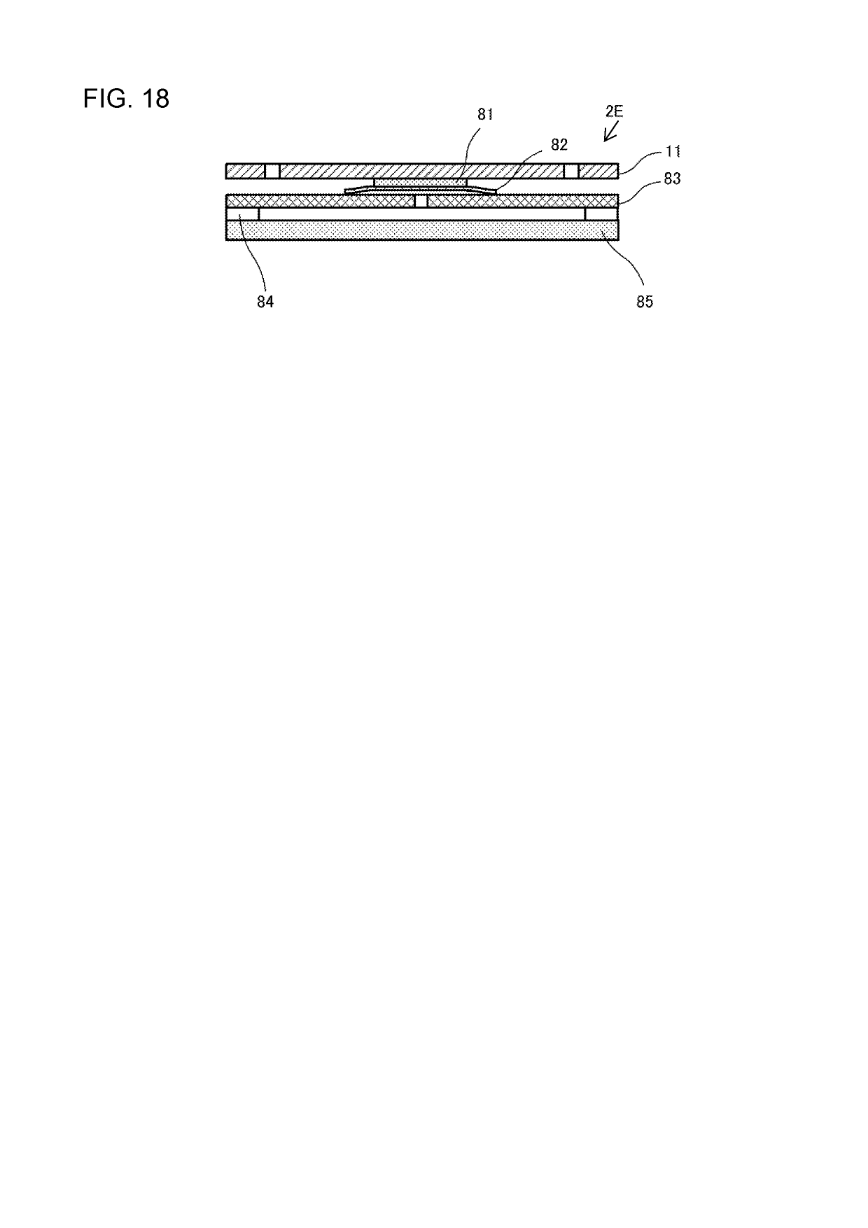

Next, FIG. 16 is an exploded perspective view of an actuator 2E according to Modification 5. The actuator 2E further includes a joining member 81, a film valve 82, a flexible plate 83, a flow-path forming member 84, and a cover member 85. The joining member 81, the film valve 82, the flexible plate 83, the flow-path forming member 84, and the cover member 85 are disposed in this order below the first vibrating plate 11. FIGS. 17 and 18 are sectional views showing the first vibrating plate 11 and a portion below the first vibrating plate 11 of the actuator 2E.

The film valve 82 is made of a flexible material and has a disk shape. The film valve 82 is disposed at the central position of the first vibrating plate 11 in plan view. The film valve 82 is joined to the lower surface of the first vibrating plate 11 with the joining member 81, which has a disk shape, interposed therebetween. The outer diameter of the film valve 82 is larger than the outer diameter of the joining member 81. In other words, a region on the outer end side of the film valve 82 is not joined to the first vibrating plate 11. Thus, the film valve 82 is joined to the first vibrating plate 11 in a state in which a region having a predetermined area on its outer end side is capable of vibrating. The film valve 82 is not limited to a disk shape and may have an annular shape.

The flexible plate 83 is a plate-shaped member. The flexible plate 83 has a through-hole at its central position in plan view. The flexible plate 83 is disposed apart from the film valve 82.

The flow-path forming member 84 is a plate-shaped member. A recessed portion for a flow path is formed in the flow-path forming member 84, and the recessed portion for a flow path is composed of a circular central region and a plurality of linear regions in plan view. The central region overlaps, in plan view (i.e., when viewed in the stacking direction of the flexible plate 83 and the flow-path forming member 84), with the through-hole formed in the flexible plate 83. One end, in the extending direction, of each of the plurality of linear regions communicates with the central region, and the other end reaches the vicinity of a different outer end of the flow-path forming member 84.

The cover member 85 is a plate-shaped member. The cover member 85 has a plurality of holes. The plurality of holes extend through the cover member 85 in the thickness direction.

When the center of the first vibrating plate 11 moves away from the flexible plate 83, the volume of a region sandwiched between the film valve 82 and the flexible plate 83 increases, thereby lowering the pressure in the region sandwiched between the film valve 82 and the flexible plate 83. As a result, as shown in FIG. 18, a region on the outer edge side (i.e., a region on the free-end side) of the film valve 82 curves toward the flexible plate 83 and comes into contact with the surface of the flexible plate 83. Thus, the through-hole at the center of the flexible plate 83 is closed, so that inflow of fluid into the through-hole is suppressed.

Accordingly, the actuator 2E according to Modification 5 can improve performance as a pump.

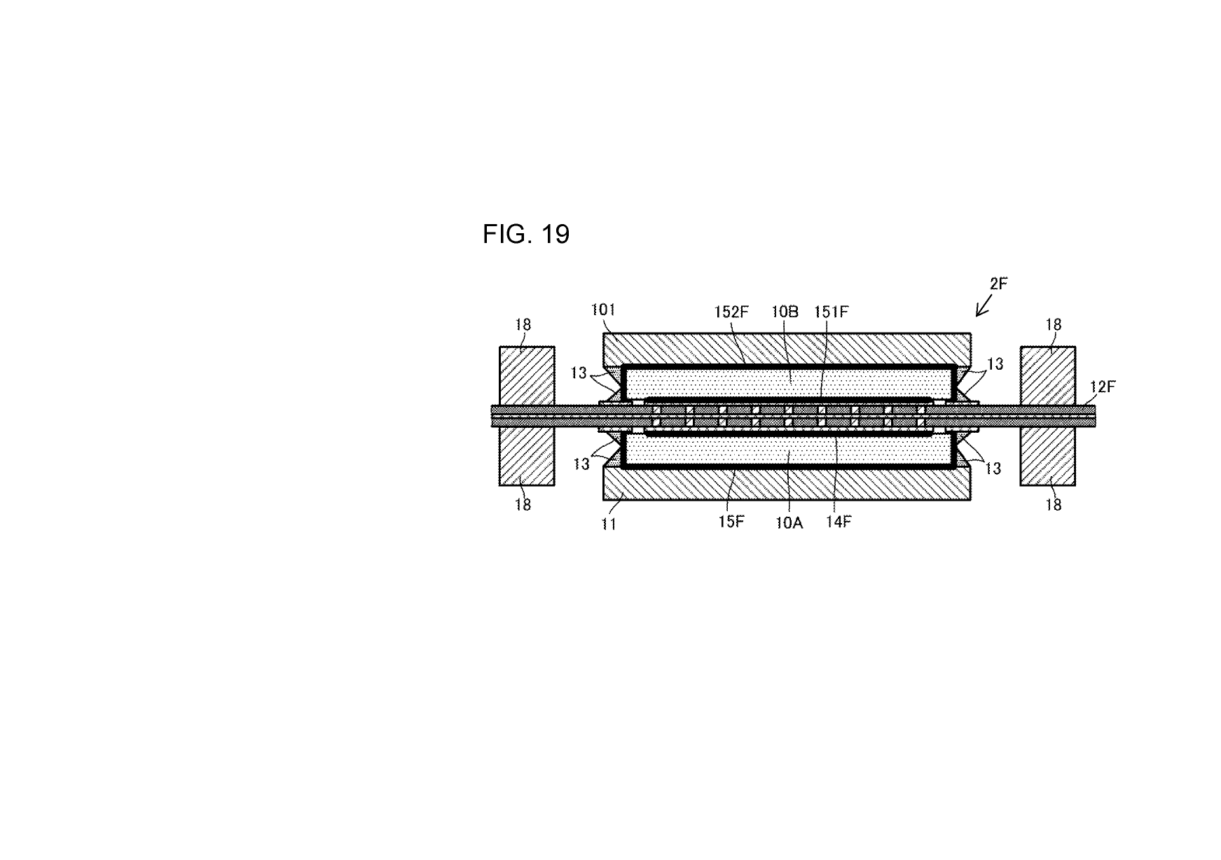

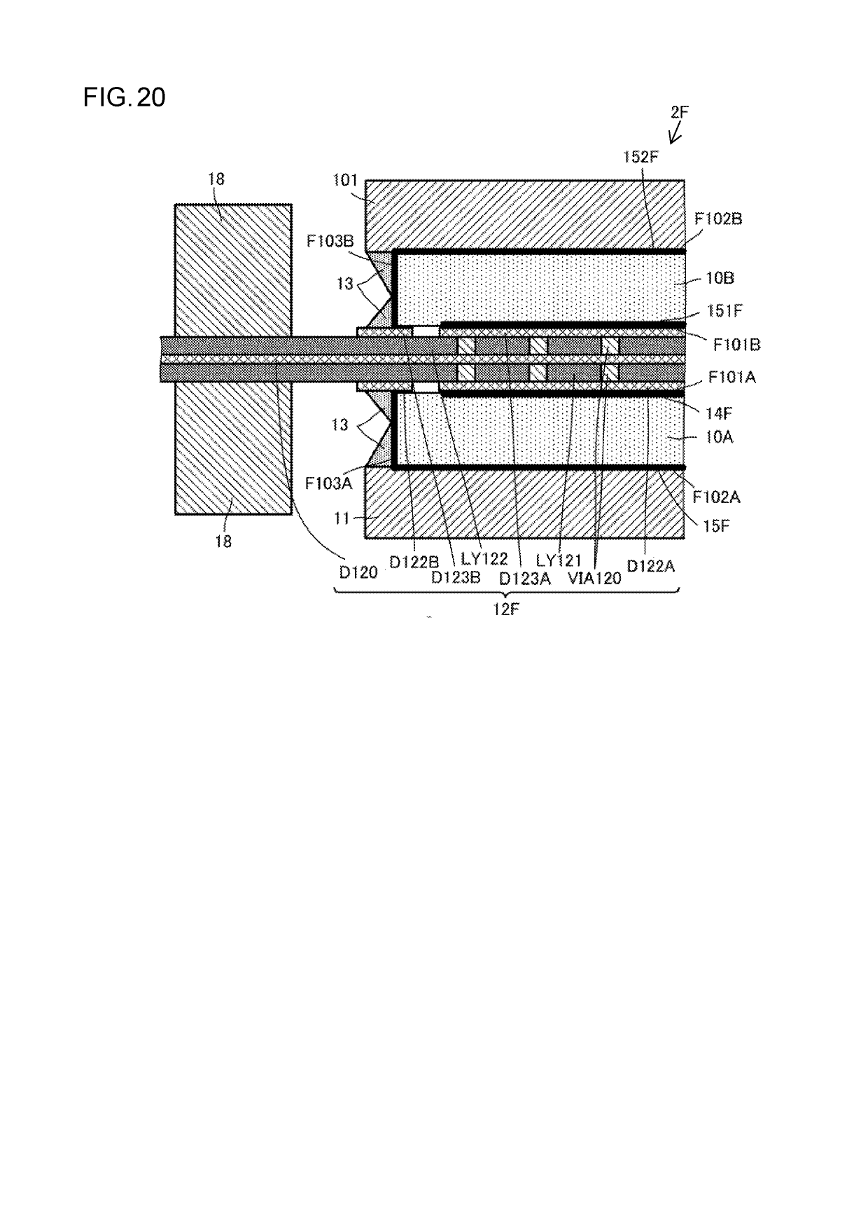

Next, FIG. 19 is a sectional view showing a structure of Modification 6 of the bimorph. FIG. 20 is a partially enlarged view of FIG. 19.

An actuator 2F according to Modification 6 differs from the actuator 2 shown in FIG. 6 in that it includes a circuit board, and in the shapes of electrode films formed on the piezoelectric bodies 10, and in that it includes a support member 18. The other configurations of the actuator 2F are the same as or similar to those of the actuator 2, and the description of the same or similar portions as or to those of the actuator 2 is omitted.

The actuator 2F includes the first piezoelectric body 10A, the second piezoelectric body 10B, a second vibrating plate 12F, and the support member 18.

The first piezoelectric body 10A includes a main surface F101A, a main surface F102A, and a side surface F103A. A first electrode 14F is formed on the main surface F101A. The first electrode 14F has a shape that does not reach the side surface F103A. A second electrode 15F is formed on the main surface F102A and the side surface F103A. The second electrode 15F has a shape reaching a corner where the side surface F103A and the main surface F101A intersect.

The second piezoelectric body 10B includes a main surface F101B, a main surface F102B, and a side surface F103B. A first electrode 151F is formed on the main surface F101B. The first electrode 151F has a shape that does not reach the side surface F103B. A second electrode 152F is formed on the main surface F102B and the side surface F103B. The second electrode 152F has a shape reaching a corner where the side surface F103B and the main surface F101B intersect.

The second vibrating plate 12F is constituted by a circuit board mainly composed of a multilayer body of an insulating layer LY121 and an insulating layer LY122. The insulating layer LY121 and the insulating layer LY122 are flexible.

An electrode pattern D120 is formed between the insulating layer LY121 and the insulating layer LY122. Electrode patterns D122A and D122B are formed on a surface of the insulating layer LY121 opposite to the surface facing the insulating layer LY122. Electrode patterns D123A and D123B are formed on a surface of the insulating layer LY122 opposite to the surface facing the insulating layer LY121. The electrode pattern D122B and the electrode pattern D123B are electrically connected by a plurality of via electrodes VIA120.

The first piezoelectric body 10A is mounted on a main surface, on the insulating layer LY121 side, of the second vibrating plate 12F. The first electrode 14F of the first piezoelectric body 10A is electrically connected to the electrode pattern D122B. The second electrode 15F of the first piezoelectric body 10A is electrically connected to the electrode pattern D122A.

The second piezoelectric body 10B is mounted on a main surface, on the insulating layer LY122 side, of the second vibrating plate 12F. The first electrode 151F of the second piezoelectric body 10B is electrically connected to the electrode pattern D123B. The second electrode 152F of the second piezoelectric body 10B is electrically connected to the electrode pattern D123A.

With such a configuration, an AC voltage for driving the actuator 2F in a bimorph mode is applied to the first electrode 14F and the second electrode 15F of the first piezoelectric body 10A and to the first electrode 151F and the second electrode 152F of the second piezoelectric body 10B.

The second vibrating plate 12F protrudes outward from both side-end portions of the first piezoelectric body 10A and the second piezoelectric body 10B. These protruding portions are supported by the support member 18 at positions away from regions where the first piezoelectric body 10A and the second piezoelectric body 10B are mounted on the second vibrating plate 12F.

The second vibrating plate 12F is flexible. As a result, a portion in which the first vibrating plate 11, the first piezoelectric body 10A, the second vibrating plate 12F, the second piezoelectric body 10B, and the third vibrating plate 101 are stacked is capable of free vibration. Thus, the actuator 2F achieves free vibration in which its outer ends are not strongly constrained.

With such a configuration, the actuator 2F can achieve the same effects as the actuator 2A. Further, the actuator 2F can apply an AC voltage to the first piezoelectric body 10A and the second piezoelectric body 10B from the outside through the second vibrating plate 12F. Thus, the actuator 2F includes a mechanism for applying the AC voltage, so that the structure can be simplified.

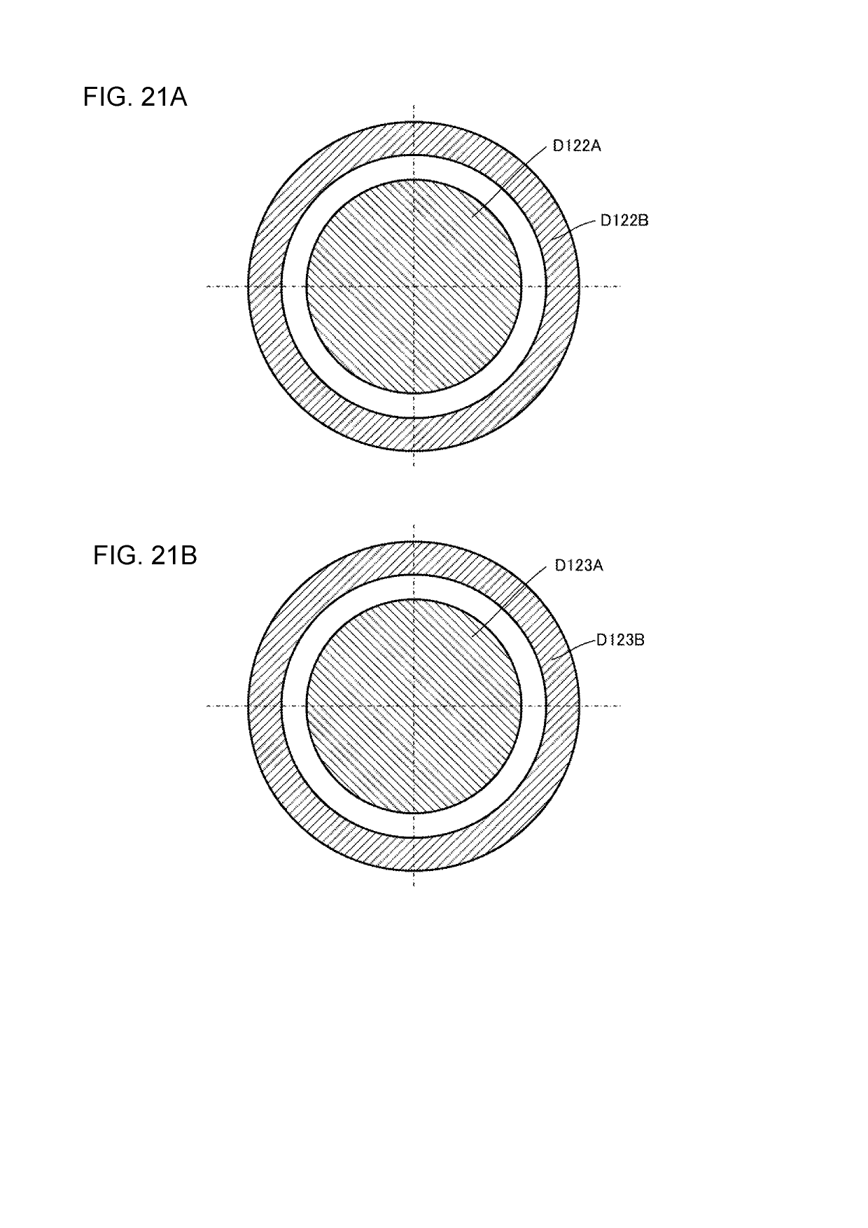

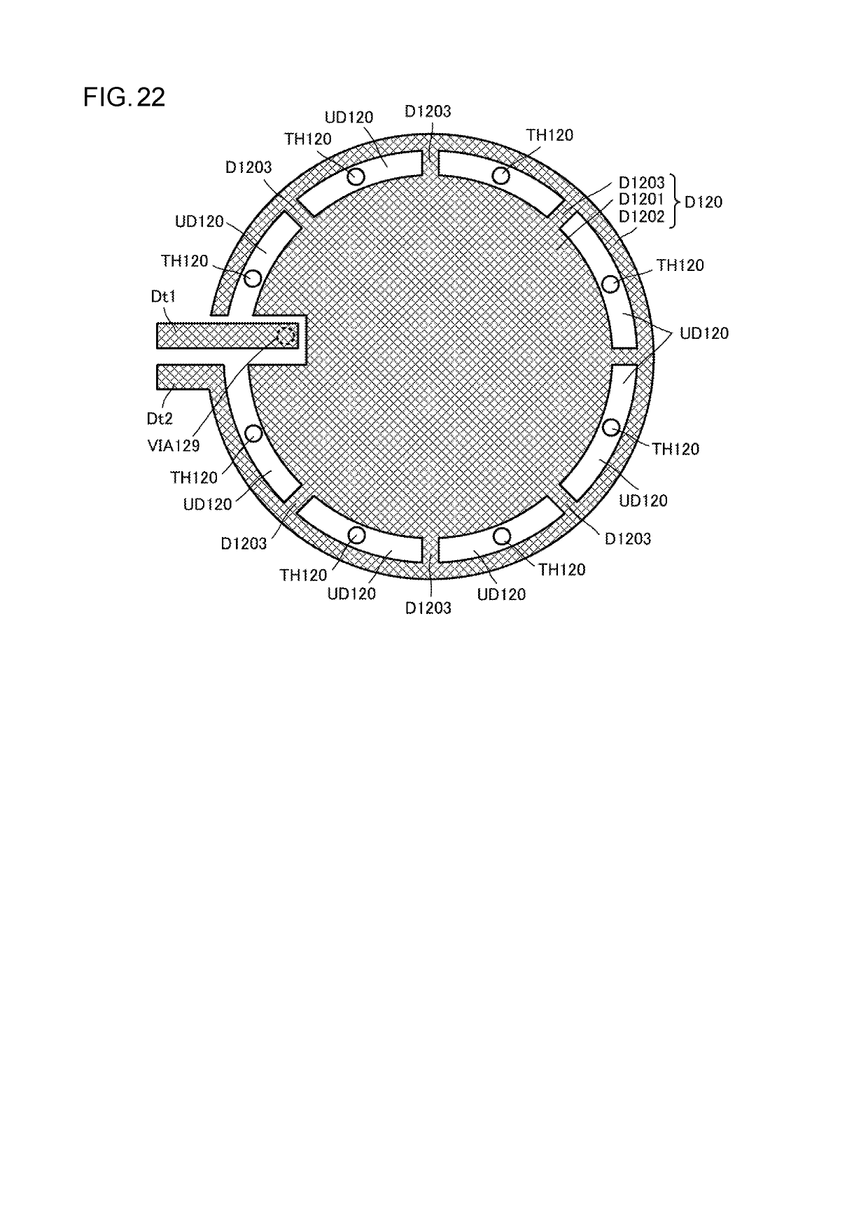

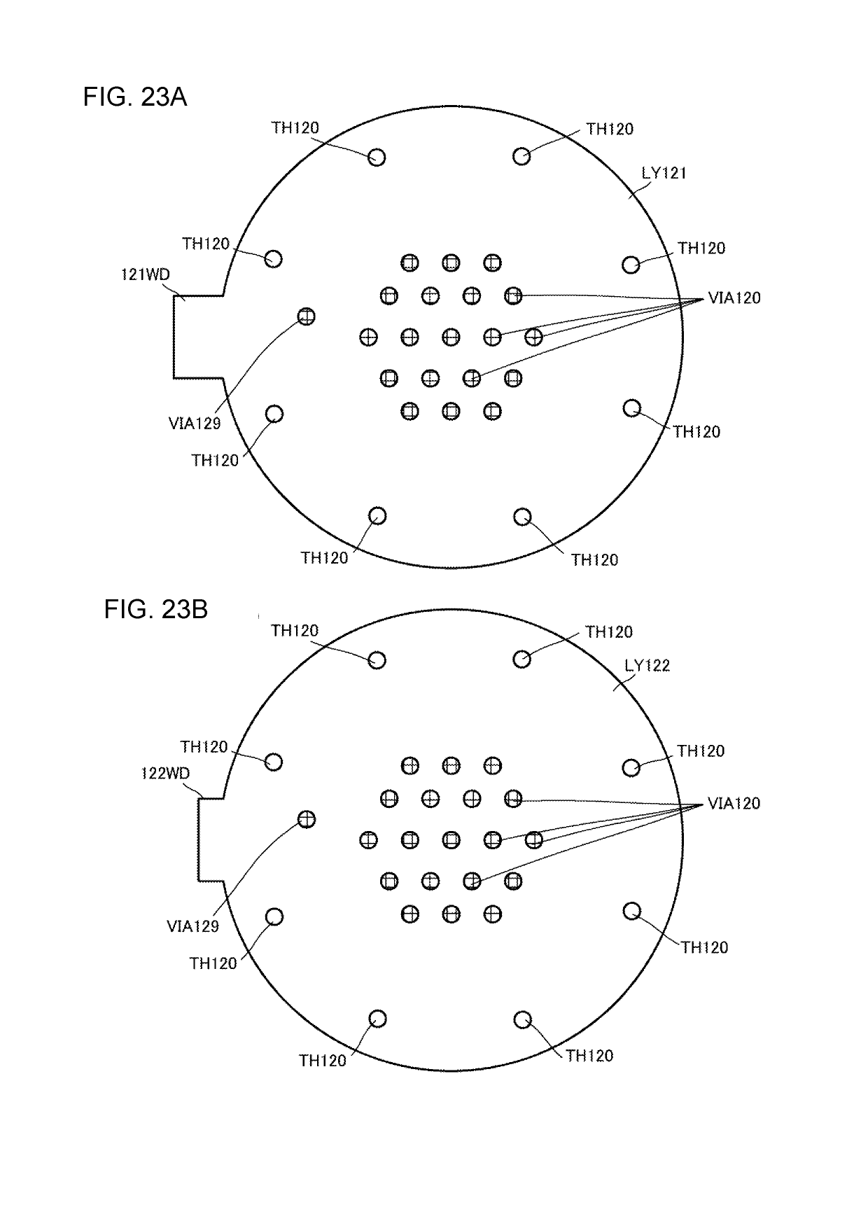

Further, the second vibrating plate 12F may have the following configuration. FIG. 21A is a plan view of the electrode patterns D122A and D122B formed on the insulating layer LY121. FIG. 21B is a plan view of electrode patterns D123A and D123B formed on the insulating layer LY122. FIG. 22 is a plan view of the electrode patterns, the via electrodes, and through-holes formed between the insulating layer LY121 and the insulating layer LY122. FIG. 23A is a plan view of the insulating layer LY121. FIG. 23B is a plan view of the insulating layer LY122.

As shown in FIG. 21A, the electrode pattern D122A is circular in plan view. The electrode pattern D122B is annular in plan view. The electrode pattern D122B surrounds the electrode pattern D122A in plan view.

As shown in FIG. 21B, the electrode pattern D123A is circular in plan view. The electrode pattern D123B is annular in plan view. The electrode pattern D123B surrounds the electrode pattern D123A in plan view.

The electrode pattern D122A and the electrode pattern D123A overlap with each other when viewed in the thickness direction of the second vibrating plate 12F (see FIGS. 19 and 20). The electrode pattern D122B and the electrode pattern D123B overlap with each other when viewed in the thickness direction of the second vibrating plate 12F (see FIGS. 19 and 20).

As shown in FIG. 22, the electrode pattern D120 is circular in plan view. The electrode pattern D120 has an annular electrode non-formed portion UD120. The electrode pattern D120 includes a central portion D1201, an outer peripheral portion D1202, and a plurality of connecting portions D1203. The central portion D1201 is circular in plan view. The outer peripheral portion D1202 is annular in plan view. The outer peripheral portion D1202 surrounds the central portion D1201 in plan view with the electrode non-formed portion UD120 interposed therebetween. The outer peripheral portion D1202 has a C-ring shape in which a portion thereof in the circumferential direction is cut away.

The plurality of connecting portions D1203 are arranged at predetermined intervals along the circumferential direction of the electrode non-formed portion UD120. The plurality of connecting portions D1203 connect the central portion D1201 and the outer peripheral portion D1202.

Wiring electrode patterns Dt1 and Dt2 are formed in the same layer as the electrode pattern D120. The wiring electrode pattern Dt1 is not connected to the electrode pattern D120, and the wiring electrode pattern Dt2 is connected to one circumferential end of the outer peripheral portion D1202.

A via electrode VIA129 is connected to one end of the wiring electrode pattern Dt1 on the side extending toward the center of the electrode pattern D120. The via electrode VIA129 passes through the insulating layer LY121 and the insulating layer LY122 (see FIGS. 23A and 23B), and is connected to the electrode patterns D122A and D123A.

When viewed in the thickness direction of the second vibrating plate 12F, the electrode non-formed portion UD120 overlaps with a plurality of through-holes TH120 formed in the insulating layers LY121 and LY122.

As shown in FIG. 23A, the insulating layer LY121 is substantially circular in plan view. The plurality of via electrodes VIA120 and the via electrode VIA129 are formed in the insulating layer LY121. When viewed in the thickness direction of the second vibrating plate 12F, the via electrode VIA129 overlaps with the electrode pattern D122A and the wiring electrode pattern Dt1.

The plurality of via electrodes VIA120 overlap with the electrode pattern D122B and the electrode pattern D120.

The insulating layer LY121 includes an extended portion 121WD. The extended portion 121WD is formed by protrusion of a portion of the circular shape.

As shown in FIG. 23B, the insulating layer LY122 is substantially circular in plan view. The plurality of via electrodes VIA120 and the via electrode VIA129 are formed in the insulating layer LY122. When viewed in the thickness direction of the second vibrating plate 12F, the via electrode VIA129 overlaps with the electrode pattern D123A and the wiring electrode pattern Dt1.

The plurality of via electrodes VIA120 overlap with the electrode pattern D123B and the electrode pattern D120.

The insulating layer LY122 includes an extended portion 122WD. The extended portion 122WD is formed by protrusion of a portion of the circular shape.

The wiring electrode patterns Dt1 and Dt2 are formed between the extended portion 121WD and the extended portion 122WD. The extended portion 122WD is shorter than the extended portion 121WD. Thus, portions of the wiring electrode patterns Dt1 and Dt2 are exposed outside the second vibrating plate 12F, and serve as external connection terminals.

As shown in FIGS. 23A and 23B, the plurality of through-holes TH120 are formed in the insulating layers LY121 and LY122. The plurality of through-holes TH120 in the insulating layer LY121 communicate with the plurality of through-holes TH120 in the insulating layer LY122. The plurality of through-holes TH120 pass through the second vibrating plate 12F in the thickness direction.

With such a configuration, the second vibrating plate 12F can apply an AC voltage to the first piezoelectric body 10A and the second piezoelectric body 10B from the outside.

Further, since the second vibrating plate 12F includes the plurality of through-holes TH120, air moves through the plurality of through-holes TH120 during operation of the actuator. Thus, the function of a fluid control device including the actuator 2F is achieved.

The configuration in which a circuit board is used as the vibrating plate is not limited to the bimorph structure and can also be applied to the unimorph structure.

It should be noted that the description of the present embodiment is to be considered illustrative in all respects and not restrictive. The scope of the present disclosure is indicated not by the above-described embodiments but by the claims. Further, it is intended that the scope of the present disclosure include all modifications within the meaning and scope equivalent to the claims.

For example, in the second embodiment shown in FIG. 7, in order to make the expansion/contraction directions of the first piezoelectric bodies 10A and 10B opposite to each other, the polarization directions of the piezoelectric bodies may be aligned, so that a drive voltage is applied to make the first vibrating plate 11 and the third vibrating plate 101 have the same potential.

Similarly, in Modification 3 of the bimorph shown in FIG. 13, in order to make the expansion/contraction directions of the first piezoelectric bodies 10A and the second piezoelectric bodies 10B opposite to each other, the polarization directions of the piezoelectric bodies may be aligned, so that a drive voltage is applied to make the first vibrating plate 11 and the third vibrating plate 101 have the same potential; in such a case, since the first connecting portion 122 and the third connecting portion 142 are at the same potential, they may overlap with each other in plan view.

1, 2, 2A, 2B, 2C, 2D, 2E, 2F actuator

10 piezoelectric body

10A first piezoelectric body

10B second piezoelectric body

11 first vibrating plate

12, 12F second vibrating plate

13 fillet

14, 14F, 151F first electrode

15, 15F, 152F second electrode

18 support member

81 joining member

82 film valve

83 flexible plate

84 flow-path forming member

85 cover member

90 vibrating plate

91 vibrating plate

101 third vibrating plate

122 first connecting portion

123 first frame body

132 second connecting portion

133 second frame body

142 third connecting portion

143 third frame body

151 third electrode

152 fourth electrode

160 spacer

161 spacer

D120, D122A, D122B, D123A, D123B electrode pattern

D1201 central portion

D1202 outer peripheral portion

D1203 connecting portion

Dt1, Dt2 wiring electrode pattern

F101A, F101B, F102A, F102B main surface

F103A, F103B side surface

LY121, LY122 insulating layer

VIA120, VIA129 via electrode

UD120 electrode non-formed portion

TH120 through-hole

121WD, 122WD extended portion

1. An actuator comprising:
a piezoelectric body having a first main surface and a second main surface;
a first electrode disposed on the first main surface;
a second electrode disposed on the second main surface;
a first vibrating plate disposed on the first electrode; and
a second vibrating plate disposed on the second electrode, wherein
a thickness of the first vibrating plate differs from a thickness of the second vibrating plate, and
fillets are provided between a peripheral edge of the piezoelectric body and the first vibrating plate and between the peripheral edge of the piezoelectric body and the second vibrating plate.

2. The actuator according to claim 1, wherein, when viewed in plan view, an outer diameter of the piezoelectric body is smaller than each of outer diameters of the first vibrating plate and the second vibrating plate.

3. The actuator according to claim 1, wherein, when viewed in plan view, an outer diameter of the piezoelectric body is greater than each of outer diameters of the first electrode and the second electrode.

4. An actuator comprising:
a first piezoelectric body having a first main surface and a second main surface;
a first electrode disposed on the first main surface;
a second electrode disposed on the second main surface;
a second piezoelectric body having a third main surface and a fourth main surface;
a third electrode disposed on the third main surface;
a fourth electrode disposed on the fourth main surface;
a first vibrating plate disposed on the first electrode;
a second vibrating plate disposed on the second electrode and the third electrode; and
a third vibrating plate disposed on the fourth electrode, wherein
fillets are provided between a peripheral edge of the first piezoelectric body and the first vibrating plate, between the peripheral edge of the first piezoelectric body and the second vibrating plate, between a peripheral edge of the second piezoelectric body and the second vibrating plate, and between the peripheral edge of the second piezoelectric body and the third vibrating plate.

5. The actuator according to claim 4, wherein, when viewed in plan view, each of outer diameters of the first piezoelectric body and the second piezoelectric body are smaller than each of outer diameters of the first vibrating plate, the second vibrating plate, and the third vibrating plate.

6. The actuator according to claim 4, wherein, when viewed in plan view, an outer diameter of the second vibrating plate is smaller than each of outer diameters of the first vibrating plate and the third vibrating plate.

7. The actuator according to claim 4, wherein, when viewed in plan view, an outer diameter of the first piezoelectric body is greater than each of outer diameters of the first electrode and the second electrode, and an outer diameter of the second piezoelectric body is greater than each of outer diameters of the third electrode and the fourth electrode.

8. The actuator according to claim 4, further comprising:
a first frame body, a second frame body, and a third frame body respectively surrounding the first vibrating plate, the second vibrating plate, and the third vibrating plate, when viewed in plan view; and
a first connecting portion, a second connecting portion, and a third connecting portion extending from outer peripheries of the first vibrating plate, the second vibrating plate, and the third vibrating plate, respectively, and connected to the first frame body, the second frame body, and the third frame body, respectively, to support the first vibrating plate, the second vibrating plate, and the third vibrating plate, respectively, wherein
the first connecting portion, the second connecting portion, and the third connecting portion do not overlap with each other when viewed in plan view.

9. The actuator according to claim 1, further comprising:
a first frame body and a second frame body respectively surrounding the first vibrating plate and the second vibrating plate, when viewed in plan view; and
a first connecting portion and a second connecting portion extending from outer peripheries of the first vibrating plate and the second vibrating plate, respectively, and connected to the first frame body and the second frame body, respectively, to support the first vibrating plate and the second vibrating plate, respectively, wherein
the first connecting portion and the second connecting portion do not overlap with each other when viewed in plan view.

10. The actuator according to claim 1, wherein
the second vibrating plate comprises a circuit board, and
the circuit board includes an insulating layer and an electrode pattern connected to an electrode of the piezoelectric body.

11. The actuator according to claim 4, wherein
the second vibrating plate comprises a circuit board, and
the circuit board includes an insulating layer and an electrode pattern connected to electrodes of the first piezoelectric body and the second piezoelectric body.

12. The actuator according to claim 2, wherein, when viewed in plan view, an outer diameter of the piezoelectric body is greater than each of outer diameters of the first electrode and the second electrode.

13. The actuator according to claim 5, wherein, when viewed in plan view, an outer diameter of the second vibrating plate is smaller than each of outer diameters of the first vibrating plate and the third vibrating plate.

14. The actuator according to claim 5, wherein, when viewed in plan view, an outer diameter of the first piezoelectric body is greater than each of outer diameters of the first electrode and the second electrode, and an outer diameter of the second piezoelectric body is greater than each of outer diameters of the third electrode and the fourth electrode.

15. The actuator according to claim 6, wherein, when viewed in plan view, an outer diameter of the first piezoelectric body is greater than each of outer diameters of the first electrode and the second electrode, and an outer diameter of the second piezoelectric body is greater than each of outer diameters of the third electrode and the fourth electrode.

16. The actuator according to claim 5, further comprising:
a first frame body, a second frame body, and a third frame body respectively surrounding the first vibrating plate, the second vibrating plate, and the third vibrating plate, when viewed in plan view; and
a first connecting portion, a second connecting portion, and a third connecting portion extending from outer peripheries of the first vibrating plate, the second vibrating plate, and the third vibrating plate, respectively, and connected to the first frame body, the second frame body, and the third frame body, respectively, to support the first vibrating plate, the second vibrating plate, and the third vibrating plate, respectively, wherein
the first connecting portion, the second connecting portion, and the third connecting portion do not overlap with each other when viewed in plan view.

17. The actuator according to claim 6, further comprising:
a first frame body, a second frame body, and a third frame body respectively surrounding the first vibrating plate, the second vibrating plate, and the third vibrating plate, when viewed in plan view; and
a first connecting portion, a second connecting portion, and a third connecting portion extending from outer peripheries of the first vibrating plate, the second vibrating plate, and the third vibrating plate, respectively, and connected to the first frame body, the second frame body, and the third frame body, respectively, to support the first vibrating plate, the second vibrating plate, and the third vibrating plate, respectively, wherein
the first connecting portion, the second connecting portion, and the third connecting portion do not overlap with each other when viewed in plan view.

18. The actuator according to claim 7, further comprising:
a first frame body, a second frame body, and a third frame body respectively surrounding the first vibrating plate, the second vibrating plate, and the third vibrating plate, when viewed in plan view; and
a first connecting portion, a second connecting portion, and a third connecting portion extending from outer peripheries of the first vibrating plate, the second vibrating plate, and the third vibrating plate, respectively, and connected to the first frame body, the second frame body, and the third frame body, respectively, to support the first vibrating plate, the second vibrating plate, and the third vibrating plate, respectively, wherein
the first connecting portion, the second connecting portion, and the third connecting portion do not overlap with each other when viewed in plan view.

19. The actuator according to claim 2, further comprising:
a first frame body and a second frame body respectively surrounding the first vibrating plate and the second vibrating plate, when viewed in plan view; and
a first connecting portion and a second connecting portion extending from outer peripheries of the first vibrating plate and the second vibrating plate, respectively, and connected to the first frame body and the second frame body, respectively, to support the first vibrating plate and the second vibrating plate, respectively, wherein
the first connecting portion and the second connecting portion do not overlap with each other when viewed in plan view.

20. The actuator according to claim 3, further comprising:
a first frame body and a second frame body respectively surrounding the first vibrating plate and the second vibrating plate, when viewed in plan view; and
a first connecting portion and a second connecting portion extending from outer peripheries of the first vibrating plate and the second vibrating plate, respectively, and connected to the first frame body and the second frame body, respectively, to support the first vibrating plate and the second vibrating plate, respectively, wherein
the first connecting portion and the second connecting portion do not overlap with each other when viewed in plan view.
